(19) United States
(12) Patent Application Publication
(10) Pub. No.: US 2026/0156983 A1
(43) Pub. Date: Jun. 4, 2026

(54) SURFACE LIGHT SOURCE DEVICE AND DISPLAY DEVICE

(71) Applicant: Enplas Corporation, Kawaguchi-shi (JP)

(72) Inventor: Takuro Momoi, Saitama (JP)

(21) Appl. No.: 19/082,228

(22) Filed: Mar. 18, 2025

(30) Foreign Application Priority Data
Mar. 28, 2024 (JP) 2024-053552

(51) Int. Cl. H10H 20/855; G02F 1/1335; G02F 1/13357; H10H 20/841; H10H 20/85; H10H 20/856; H10H 29/24; H10H 29/855

(52) U.S. Cl. CPC H10H 20/855; G02F 1/133603; G02F 1/133605; G02F 1/133607; H10H 20/841; H10H 20/8502; H10H 20/856; H10H 29/24; H10H 29/855

(57) ABSTRACT

A surface light source device of the present invention includes a substrate, a plurality of light-emitting elements, a light flux controlling member, and a light diffusion plate. The light flux controlling member includes an incidence surface, a total reflection surface, and a refractive emission surface. 50% or more of light that is reflected by the total reflection surface reaches a surface on the substrate side within a distance of L/2 from an intersection C1, where L is a distance between optical axes OA of the plurality of light-emitting elements, and the intersection C1 is an intersection of the optical axes OA of the light-emitting elements and the substrate.

### CROSS REFERENCE TO RELATED APPLICATIONS

This application is entitled to and claims the benefit of Japanese Patent Application No. 2024-53552, filed on Mar. 28, 2024, the disclosure of which including the specification, drawings and abstract is incorporated herein by reference in its entirety.

### Technical Field

The present invention relates to a surface light source device and a display device.

### Background Art

Display devices such as liquid crystal displays use a surface light source device that includes a plurality of light-emitting elements. FIG. 1A is a sectional view of light flux controlling member (lens) 30 for controlling light from light-emitting element 20 disclosed in PTL 1. FIG. 1B is a sectional view of surface light source device 10 where a plurality of light flux controlling members 30 is disposed. Light flux controlling member 30 illustrated in FIG. 1A includes: incidence surface 31 that allows incidence of light from light-emitting element 20, total reflection surface (first reflection portion) 32 for totally reflecting light entering from incidence surface 31, flat surface reflection surface (second reflection portion) 33 continuously disposed on the outside of total reflection surface 32 and configured to reflect light, and emission surface 34 for emitting light. As illustrated in FIG. 1B, a plurality of light flux controlling members 30 for controlling light from such a light-emitting element 20 is arranged on substrate 11, and light diffusion plate 12 is disposed over the plurality of light flux control members 30 so as to be used as surface light source device 10.

### CITATION LIST

### Patent Literature

### PTL 1

Japanese Patent Application Laid-Open No. 2022-082802

### SUMMARY OF INVENTION

### Technical Problem

Since light flux controlling member 30 with the above-described configuration can have a reduced height, the thickness of surface light source device 10 including the plurality of light flux controlling members 30 can be reduced, which is suitable for thin backlight.

However, as illustrated in FIG. 1A, in light flux controlling member 30, light that is reflected by total reflection surface 32 and by flat surface reflection surface 33 may be reflected by emission surface 34 having a constant inclination without being emitted out of light flux controlling member 30. Such light is reflected inside light flux controlling member 30 and emitted from the upper part to reach light diffusion plate 12 located immediately above, thus brightening the region in the vicinity immediately above light flux controlling member 30 (see the broken line in FIG. 1A). Such light distribution may degrade the quality of light in surface light source device 10.

In addition, as illustrated in FIG. 1B, light flux controlling member 30 may have light that is emitted from light-emitting element 20 and directly emitted from emission surface 34 having a constant inclination without reaching total reflection surface 32 and flat surface reflection surface 33. In addition, as illustrated in FIG. 1B, light flux controlling member 30 may have light that is reflected by total reflection surface 32 and emitted from emission surface 34 having a constant inclination. Such light tends to travel approximately parallel to the substrate and reach the adjacent light flux controlling member 30. Such light reaches light diffusion plate 12 in the region in the vicinity immediately above the light flux controlling member, thus unintentionally brightening the region in the vicinity immediately above the adjacent light flux controlling member (see the broken line in FIG. 1B). In a surface light source device having a local dimming configuration, in which the light-emitting surface is divided into a plurality of regions and the brightness is controlled for each region, light that has entered light flux controlling member 30 above the adjacent non-lighting light-emitting element 20 brightens the area above non-lighting light-emitting element 20, and this light distribution may degrade the quality of light in the surface light source device.

An object of the present invention is to provide a surface light source device including a light flux controlling member that can suppress degradation in the quality of light even in a surface light source device that supports local dimming, and a display device including the surface light source device.

### Solution to Problem

The present invention relates to the following surface light source device.
[1] A surface light source device including: a substrate; a plurality of light-emitting elements disposed on the substrate, each light-emitting element including a light reflection film at a top surface; a plurality of light flux controlling members respectively disposed to cover the plurality of light-emitting elements; and a light diffusion plate disposed above the plurality of light flux controlling members, in which the light flux controlling member includes: an incidence surface disposed on a rear side, and configured to allow incidence of light emitted from the light-emitting element, a total reflection surface disposed on a front side, and configured to totally reflect, toward the substrate side, a part of light entering from the incidence surface, and a refractive emission surface disposed on the front side and outside of the total reflection surface, and configured to emit light reflected by the total reflection surface and the other part of light entering from the incidence surface, while refracting the light, and in which 50% or more of light that is reflected by the total reflection surface and emitted from the refractive emission surface reaches a surface on the substrate side within a distance of L/2 from an intersection C1, where L is a distance between optical axes OA of the plurality of light-emitting elements adjacent to each other, and the intersection C1 is an intersection of the optical axes OA of the light-emitting elements and the substrate.
[2] The surface light source device according to [1], in which light that enters through the incidence surface and is emitted from the refractive emission surface not through the total reflection surface includes light that reaches the light diffusion plate within a distance of L/2 from an intersection C2 and light that reaches the light diffusion plate at a distance exceeding L from the intersection C2, where the intersection C2 is an intersection of the optical axes OA of the light-emitting elements and the light diffusion plate.
[3] The surface light source device according to [1] or [2], in which in a see-through plan view of the light flux controlling member, an inner edge of the total reflection surface is located on inside of an outer edge of the light-emitting element.
[4] The surface light source device according to any one of [1] to [3], in which the light flux controlling member includes a blind spot region disposed between the total reflection surface and the refractive emission surface, and in which light from the light-emitting element does not reach the blind spot region.
[5] A display device including the surface light source device according to any one of [1] to [4].

### Advantageous Effects of Invention

According to the present invention, a surface light source device including a light flux controlling member that can suppress degradation in light quality can be provided.

### BRIEF DESCRIPTION OF DRAWINGS

FIG. 1A is a diagram illustrating a known light flux controlling member, and FIG. 1B is a diagram illustrating a surface light source device including a plurality of known light flux controlling members;

FIGS. 2A and 2B are diagrams illustrating a surface light source device according to the embodiment;

FIGS. 3A and 3B are sectional views illustrating the surface light source device according to the embodiment;

FIG. 4 is a diagram illustrating optical paths in the surface light source device according to the embodiment and a known surface light source device;

FIGS. 5A to 5E are diagrams illustrating a light flux controlling member according to the embodiment;

FIGS. 6A and 6B are diagrams illustrating optical paths in the light flux controlling member according to the embodiment;

FIG. 7A is a diagram illustrating a light flux controlling member of an example, FIG. 7B is a diagram illustrating a light flux controlling member of a comparative example, and FIG. 7C is a graph illustrating a luminance distribution in the light flux controlling members of the example and the comparative example;

FIG. 8A is a graph illustrating a luminance distribution in the light flux controlling member of the example, and FIG. 8B is a graph illustrating a luminance distribution in the light flux controlling member of the comparative example; and

FIG. 9 is a graph illustrating a result of comparison between luminance distributions of the light flux controlling members of the example and the comparative example.

### DESCRIPTION OF EMBODIMENTS

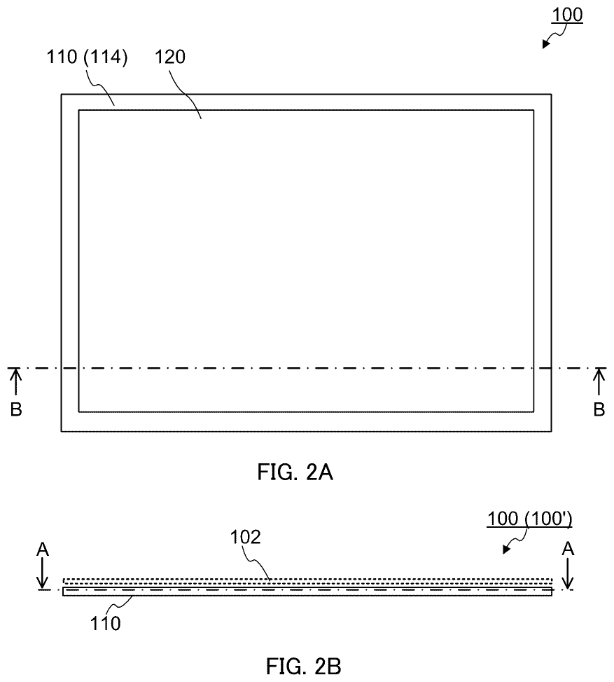

An embodiment of the present invention is elaborated below with reference to the accompanying drawings. In the following description, a surface light source device suitable for a backlight or the like of a liquid crystal display apparatus is described as a typical example of a surface light source device according to the present invention (see FIG. 2A). Such a surface light source device can be used as display device 100′ when combined with display member 102 (e.g., a liquid crystal panel) to which light from the surface light source device is applied (see FIG. 2B).

### EMBODIMENTS

### Configurations of Surface Light Source Device and Light-Emitting Device

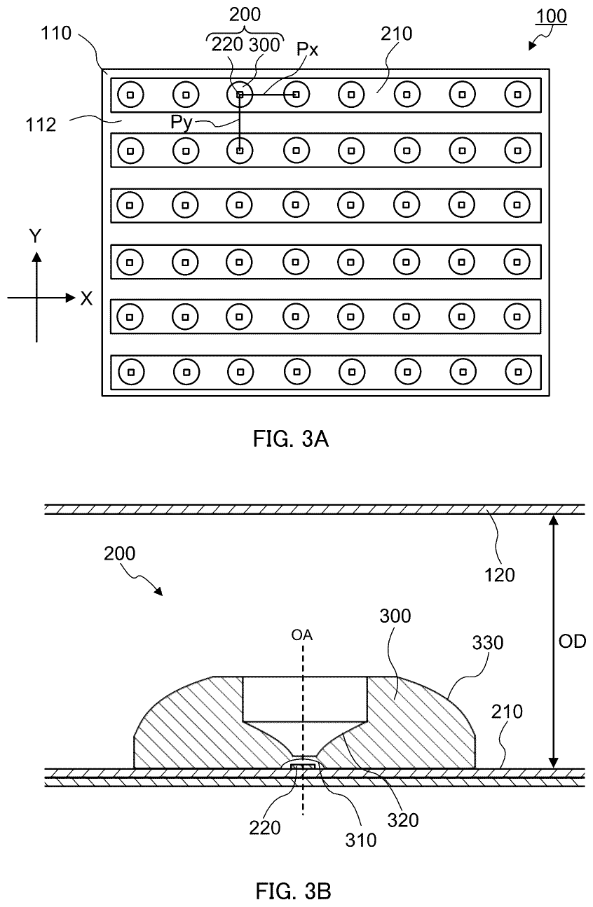

FIGS. 2A and 2B are diagrams illustrating a configuration of surface light source device 100 according to the embodiment of the present invention. FIG. 2A is a plan view of surface light source device 100, and FIG. 2B is a front view. FIG. 3A is a schematic cross-sectional view taken along line A-A of FIG. 2B, and FIG. 3B is a partially enlarged cross-sectional view taken along line B-B of FIG. 2A. FIG. 3A is a schematic diagram illustrating an arrangement of a plurality of light-emitting devices 200 in surface light source device 100, and FIG. 3B is a cross-sectional view illustrating a configuration of light-emitting device 200.

As illustrated in FIG. 2A to 3B, surface light source device 100 according to the present embodiment includes housing 110, the plurality of light-emitting devices 200 and light diffusion plate 120. As illustrated in FIG. 3A, the plurality of light-emitting devices 200 is disposed on bottom plate 112 of housing 110. The inner surface of bottom plate 112 functions as a diffusive reflection surface. In addition, top plate 114 of housing 110 is provided with an opening. Light diffusion plate 120 is disposed to close the opening, and functions as a light-emitting surface. The size of the light-emitting surface is not limited, but, for example, is approximately 400 mm×approximately 700 mm.

As illustrated in FIG. 3A, in the present embodiment, light-emitting device 200 is fixed on substrate 210 fixed at a predetermined position of bottom plate 112 of housing 110. In the present embodiment, substrate 210 has a bar shape. Light-emitting device 200 includes light flux controlling member 300 (lens) for controlling the light distribution of light from light-emitting element 220. Note that, although the light-emitting element 220 is originally not visible since it is disposed below the light flux control member 300, it is illustrated in FIG. 3A for explanatory purposes.

As illustrated in FIG. 3A, in the present embodiment, the plurality of light-emitting devices 200 is disposed side by side in the X direction at even intervals, and disposed side by side at even intervals also in the Y direction perpendicular to the X direction. As illustrated in FIG. 3A, light-emitting device 200 may be disposed such that Py is greater than Px or equal to Px, where Px is the center-to-center distance between two light-emitting devices 200 adjacent to each other in the X direction and Py is the center-to-center distance of two light-emitting devices 200 adjacent to each other in the Y direction. In the present embodiment, Py is greater than Px. In addition, in the present embodiment, Px coincides with distance L between optical axes OA of adjacent light-emitting elements described later.

FIG. 3B is a sectional view of light-emitting device 200 illustrated in FIG. 3A. As illustrated in FIG. 3B, in light-emitting device 200, light flux controlling member 300 (lens) is disposed above light-emitting element 220.

Light flux controlling member 300 includes incidence surface 310 that allows incidence of light emitted from light-emitting element 220, total reflection surface 320 that totally reflects, toward substrate 210 side, a part of light entering from incidence surface 310, and refractive emission surface 330 for emitting another part of the light reflected by total reflection surface 320 and light entering from incidence surface 310 while refracting the light. The configuration of light flux controlling member 300 is elaborated later.

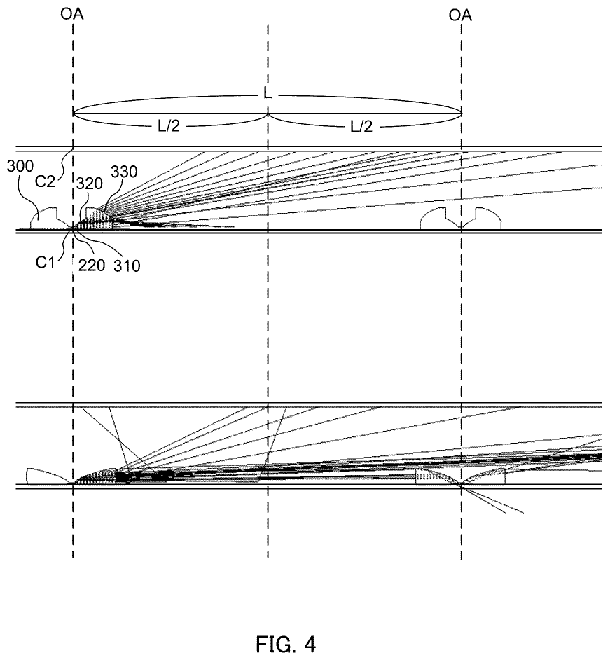

The upper diagram of FIG. 4 is a diagram illustrating an optical path in surface light source device 100 according to the present embodiment. The lower diagram of FIG. 4 is a diagram illustrating an optical path in a known surface light source device for reference purposes. As can be seen in FIG. 4, the surface light source device according to the present embodiment diffuses a greater amount of light in the region between adjacent light-emitting devices 200. In this manner, the surface light source device in the present embodiment suppresses degradation in light quality.

More specifically, the light distribution in light flux controlling member 300 of the surface light source device of the present embodiment is as follows. Specifically, as illustrated in FIGS. 4, 50% or more of the light that is reflected by total reflection surface 320 and emitted from refractive emission surface 330 reaches the surface on the substrate side within a distance of L/2 from intersection C1, where L is the distance between optical axes OA of adjacent light-emitting elements 220, and intersection C1 is the intersection of optical axis OA of light-emitting element 220 and substrate 210. In the following description, this condition is appropriately referred to as light distribution condition 1.

In addition, light entering from incidence surface 310 that is emitted from refractive emission surface 330 not through total reflection surface 320 includes light that reaches light diffusion plate 120 within a distance of L/2 from intersection C2, and light that reaches light diffusion plate 120 at a distance exceeding L from intersection C2, where intersection C2 is the intersection between optical axis OA of light-emitting element 220 and light diffusion plate 120. In the following description, this condition is appropriately referred to as light distribution condition 2. Specifically, in the present embodiment, the light entering from incidence surface 310 that is emitted from refractive emission surface 330 not through total reflection surface 320 is spread over a wide range to also reach light diffusion plate 120 at a position close to light flux controlling member 300 and light diffusion plate 120 at a position remote from light flux controlling member 300. With the above-described light distribution, the degradation in light quality in the surface light source device can be suppressed. More specifically, in the surface light source device of the present embodiment, OD robustness and dimming performance are improved. Details will be described later with reference to simulations.

Now configurations in light-emitting device 200 are described below.

### Light-Emitting Element

Light-emitting element 220 is a light source of surface light source device 100, and is mounted on substrate 210. Light-emitting element 220 is a light-emitting diode (LED) such as a white light-emitting diode, for example. In addition, light-emitting element 220 is provided with a surface light reflection film on the top surface of light-emitting element 220. In this manner, in light-emitting element 220, there is almost no emission of the light from the top surface, and the light is mainly emitted from the side surface. The light reflection film is a DBR (Distributed Bragg Reflector) film, for example. The size of light-emitting element 220 is not limited, but preferably light-emitting element 220 has a rectangular shape in plan view, with each side having a length of 0.1 mm to 1.0 mm, more preferably 0.2 mm to 0.7 mm. In the present embodiment, light-emitting element 220 has a rectangular (square) shape in plan view.

The top surface of light-emitting element 220 is covered with a light reflection film, and light is emitted from the side surface of light-emitting element 220. In a plan view of light-emitting element 220, light is radially emitted from the side surface of light-emitting element 220.

Light-emitting element 220 has optical axis OA. Optical axis OA is the center of the entirety of radially emitted light. In the present embodiment, optical axis OA of light-emitting element 220 is a straight line that is perpendicular to substrate 210 and passes through the center of gravity of the top surface (light reflection film) of light-emitting element 220.

Light-emitting element 220 is disposed inside incidence surface 310 such that light emitted from light-emitting element 220 impinges on incidence surface 310 of light flux controlling member 300. The region between light-emitting element 220 and incidence surface 310 may be sealed with a light transmissive resin, or may not be sealed such that air is present between light-emitting element 220 and incidence surface 310. In the present embodiment, light-emitting element 220 is not sealed with a light transmissive resin, and air is present between light-emitting element 220 and incidence surface 310. In the case where the region between light-emitting element 220 and incidence surface 310 is sealed with a light transmissive resin, the refractive index of the light transmissive resin is preferably close to the refractive index of light flux controlling member 300 in order to suppress light refraction.

### Light Flux Controlling Member

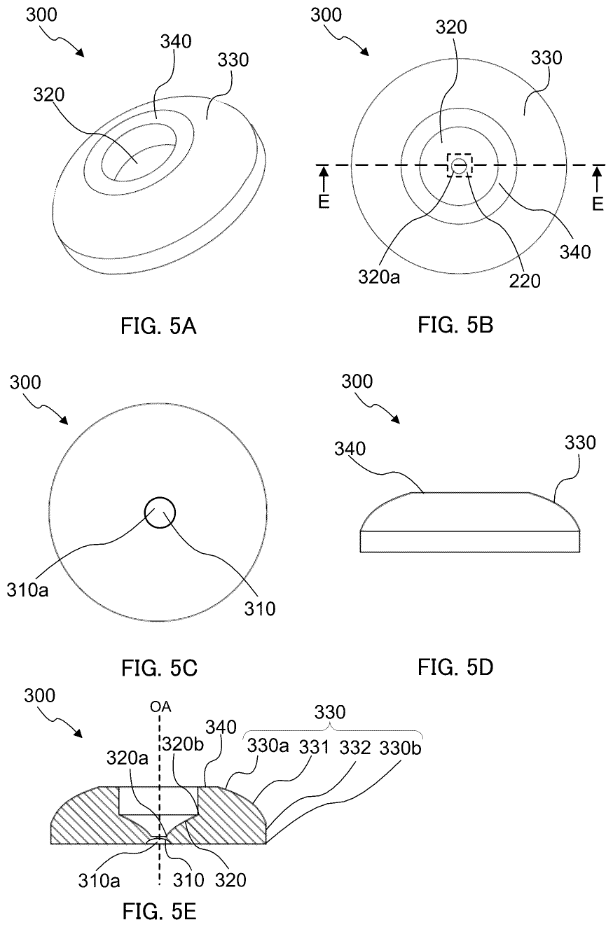

FIG. 5A is a perspective view of light flux controlling member 300, FIG. 5B is a plan view, FIG. 5C is a bottom view, FIG. 5D is a side view, and FIG. 5E is a sectional view taken along line E-E of FIG. 5B.

Light flux controlling member 300 is an optical member that controls the distribution of light emitted from light-emitting element 220, and light flux controlling member 300 is disposed on substrate 210. Light flux controlling member 300 is bonded to substrate 210 using light transmissive resin, for example. Light flux controlling member 300 has a shape that is rotationally symmetrical (circularly symmetrical) about optical axis OA. Light flux controlling member 300 has a substantially disk-like external shape that is circular in plan view and in bottom view. The refractive index of light flux controlling member 300 needs only to be 1.4 to 1.6, for example. In the present embodiment, light flux controlling member 300 includes incidence surface 310, total reflection surface 320, refractive emission surface 330, and blind spot region 340. Note that, each of these configurations also has a shape that is rotationally symmetrical (circularly symmetrical) about optical axis OA. Each configuration is described below.

### Incidence Surface

Incidence surface 310 is disposed on the rear side of light flux controlling member 300. More specifically, incidence surface 310 is disposed on the rear side of light flux controlling member 300 to intersect optical axis OA of light-emitting element 220 (see FIG. 3B). Incidence surface 310 is the inner surface of recess 310a where light-emitting element 220 is disposed. Recess 310a needs only to be designed as necessary in a size with which light-emitting element 220 can be disposed. In the present embodiment, recess 310a has a substantially hemispherical shape with incidence surface 310 as the inner surface. In this manner, light emitted from light-emitting element 220 enters the interior of light flux controlling member 300 from incidence surface 310 without being substantially refracted.

### Total Reflection Surface

Total reflection surface 320 is a surface disposed on the front side of light flux controlling member 300 to totally reflect toward substrate 210 side a part of light entering from incidence surface 310.

As described above, 50% or more of the light that is totally reflected at total reflection surface 320 and emitted from refractive emission surface 330 reaches the surface on substrate 210 side within a distance of L/2 from intersection C1 (hereinafter appropriately referred to also as region within a distance of L/2), where L is the distance between optical axes OA of adjacent light-emitting elements 220, and intersection C1 is the intersection of optical axis OA of light-emitting element 220 and substrate 210. In the present embodiment, the surface on substrate 210 side is a reflection surface (e.g., a reflection member such as a diffusive reflection sheet) disposed on substrate 210, and light having reached the surface on substrate 210 side is diffused and reflected to reach light diffusion plate 120.

The above-described light distribution due to total reflection surface 320 and refractive emission surface 330 generates light that illuminates a region around light-emitting device 200 (light flux controlling member 300), and a smooth mountain-shaped luminance distribution is obtained for light emitted from one light-emitting device 200 in the surface light source device, thus suppressing degradation in light quality. Details of this will be described later with reference to simulations.

The percentage of light totally reflected at total reflection surface 320 that reaches the region within a distance of L/2 may be appropriately set in accordance with the values of Px and Py described above (see FIG. 3A). For example, it is also possible to configure such that 60% or more, 70% or more, 80% or more, or 90% or more of the light reflected at the total reflection surface 320 reaches the region within a distance of L/2.

More specifically, in the case where Px and Py are increased to reduce the number of light-emitting devices 200 in surface light source device 100 (see FIG. 3A), it is preferable to reduce the totally reflected light that reaches the region within a distance of L/2 in order to suppress excessive brightness in the region in the vicinity immediately above light flux controlling member 300.

Total reflection surface 320 needs only to be appropriately designed to obtain the above-described light distribution. In the present embodiment, as illustrated in the cross-sectional view including optical axis OA of FIG. 5E, total reflection surface 320 includes a curved surface in which the gradient of the tangent gradually becomes parallel to the substrate 210 as it extends from inner edge 320a of the total reflection surface on the center side of light flux controlling member 300 toward outer edge 320b of the total reflection surface substrate 210. In addition, total reflection surface 320 is a curved surface with increasing distance from substrate 210 as it extends away from optical axis OA.

As illustrated in FIG. 5B, in a see-through plan view of light flux controlling member 300, inner edge 320a of the total reflection surface is preferably disposed on the inside of the outer edge of light-emitting element 220. In this manner, light emitted from light-emitting element 220 does not reach total reflection surface 320 but travels to the region directly above light flux controlling member 300 from the region surrounded by inner edge 320a of the total reflection surface and reaches light diffusion plate 120 in the region in the vicinity immediately above light flux controlling member 300, thus suppressing degradation in light quality.

In addition, in the present embodiment, total reflection surface 320 has a ring shape in a plan view of light flux controlling member 300 as illustrated in FIG. 5B.

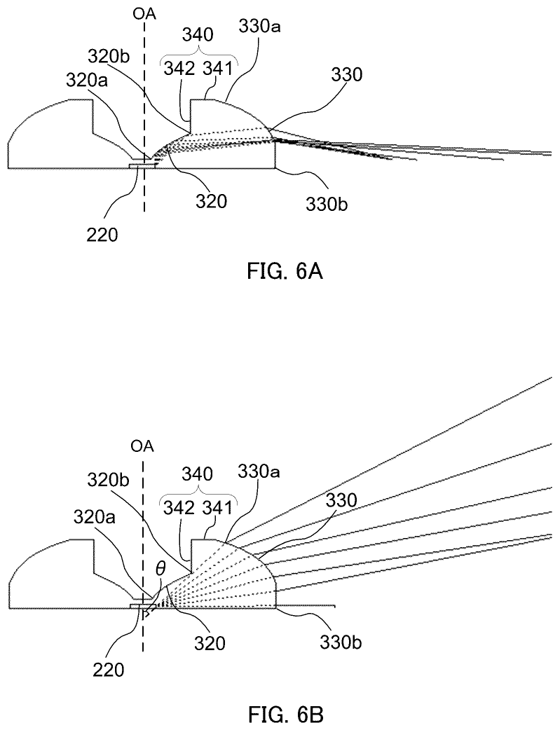

In addition, when the angle of light that is emitted in parallel to optical axis OA is 0° and the angle of light that is emitted from light-emitting element 220 in parallel to substrate 210 is 90°, total reflection surface 320 is preferably designed as illustrated in FIG. 6A and B in terms of the relationship with the light angles.

Specifically, as illustrated in FIG. 6A, it is preferable that the design be such that, in the cross section including optical axis OA, the light emitted at an angle of approximately 0 to 46° reaches total reflection surface 320.

### Refractive Emission Surface

Refractive emission surface 330 is disposed on the front side of light flux controlling member 300 and on the outside of total reflection surface 320, the light reflected by total reflection surface 320 and the other part of light entering from incidence surface 310 (light that enters from incidence surface 310 and does not reach total reflection surface 320) are emitted while being refracted.

In the present embodiment, refractive emission surface 330 is configured such that light entering from incidence surface 310 that is emitted from refractive emission surface 330 not through total reflection surface 320 includes light that reaches light diffusion plate 120 within a distance of L/2 from intersection C2, and light that reaches light diffusion plate 120 at a distance exceeding L from intersection C2, where intersection C2 is the intersection between optical axis OA of light-emitting element 220 and light diffusion plate 120 (see FIG. 4) as described above. In this manner, the light emitted from refractive emission surface 330 is spread over a wide range, thus suppressing the degradation in light quality in the surface light source device. Details will be described later with reference to simulations.

Refractive emission surface 330 is preferably designed as necessary to obtain the above-described light distribution. In the present embodiment, as illustrated in FIG. 5E, refractive emission surface 330 includes curved surface portion 331 in which the gradient of the tangent gradually becomes perpendicular to the substrate as it extends from inner edge 330a of the refractive emission surface on the center side of light flux controlling member 300 toward outer edge 330b of the refractive emission surface. The curved surface portion 331 becomes closer to substrate 210 as the distance from optical axis OA increases. In addition, in the present embodiment, refractive emission surface 330 includes outer periphery portion 332. Outer periphery portion 332 is a portion where the inclination of the tangent does not change and includes outer edge 330b of the refractive emission surface. In the present embodiment, outer periphery portion 332 is perpendicular to substrate 210.

In addition, in the present embodiment, refractive emission surface 330 has a ring shape in a plan view of light flux controlling member 300 as illustrated in FIG. 5B.

In addition, refractive emission surface 330 is preferably designed as illustrated in FIG. 6B in terms of the relationship with the angle of light emitted from light-emitting element 220.

Specifically, FIG. 6B illustrates light emitted at an angle of approximately 47 to 90° in the cross section including optical axis OA, but refractive emission surface 330 is preferably designed such that light at an angle of approximately 47 to 90° reaches.

Inner edge 330a of the refractive emission surface is disposed at a position where the light with the smallest angle to optical axis OA reaches among the light emitted from light-emitting element 220 that directly reaches refractive emission surface 330 not through total reflection surface 320. Note that, the region on the inside of inner edge 330a of the refractive emission surface is blind spot region 340 described later. In addition, as illustrated in FIG. 5E, inner edge 330a of the refractive emission surface in the direction along optical axis OA is located on the front side of light flux controlling member 300 relative to outer edge 320b of the total reflection surface.

Inner edge 330a of the refractive emission surface may be configured such that arriving light is emitted without refraction (emitted straight), or that the light is refracted and emitted in a direction away from optical axis OA. In the present embodiment, it is configured such that the light having reached inner edge 330a of the refractive emission surface is refracted and emitted in a direction away from optical axis OA as illustrated in FIG. 6B.

Note that, refractive emission surface 330 emits most of the light while refracting it; however, as described above, it is not necessarily a surface that refracts all incident light. Depending on the angle, some light may be emitted straight.

### Blind Spot Region

Blind spot region 340 is a region where light from light-emitting element 220 does not reach, between total reflection surface 320 and refractive emission surface 330 on the front side of light flux controlling member 300. More specifically, in the present embodiment, blind spot region 340 is a region between outer edge 320b of the total reflection surface (see FIG. 6A) and inner edge 330a of the refractive emission surface (see FIG. 6B). Blind spot region 340 is a region where light from light-emitting element 220 that is emitted from the center of the side surface of light-emitting element 220 in the height direction (excluding stray light) substantially does not reach, and thus does not affect the light distribution. Accordingly, while blind spot region 340 does not directly affect the light distribution regardless of the configuration, the configuration of blind spot region 340 is to some extent determined as a result of designing refractive emission surface 330 and total reflection surface 320 related to light distribution to achieve the desired light distribution.

In the present embodiment, blind spot region 340 includes top surface portion 341, which is located at the top of light flux controlling member 300 and includes a flat surface parallel to the substrate, and inner peripheral surface 342 that is perpendicular to the substrate. Top surface portion 341 has a ring-shape (see FIG. 5B) that is rotationally symmetrical (circularly symmetrical) about optical axis OA in plan view. Inner peripheral surface 342 has a configuration that is rotationally symmetrical about optical axis OA and corresponds to the inner surface of a cylinder.

When the height (the length in the direction parallel to optical axis OA) of light flux controlling member 300 is set as 1, the height (the length in the direction parallel to optical axis OA) of blind spot region 340 is approximately 0.5 to 0.6. When the diameter of light flux controlling member 300 is set as 1, the width of blind spot region 340 (the width of blind spot region 340 with a ring shape in plan view) is approximately 0.1 to 0.2.

The shape of blind spot region 340 is not limited as long as the desired light flux control of the light flux controlling member is not hindered, and is not limited to the shape illustrated FIGS. 6A and 6B. More specifically, when θ(°) is set as the angle to optical axis OA of the light that is emitted from light-emitting element 220 to reach inner edge 330a of the refractive emission surface without reaching total reflection surface 320, blind spot region 340 needs to be configured to have a surface whose angle to optical axis OA is θ or smaller (see FIG. 6B). In addition, the surface having an angle of θ or smaller needs only to be connected to outer edge 320b of the total reflection surface. In addition, in the case where the surface having an angle of θ or smaller is a surface having an angle smaller than θ, the blind spot region angle includes a surface having an angle greater than θ on the outside of the surface having an angle smaller than θ.

In the present embodiment, the surface having an angle of θ or smaller (the surface having an angle smaller than θ) corresponds to inner peripheral surface 342, and is connected to outer edge 320 b of the total reflection surface, with an angle of substantially 0° with respect to optical axis OA. It should be noted that, a releasing taper from the metal mold may be provided for the ease of molding. On the other hand, the surface having an angle greater than θ corresponds to top surface portion 341, and top surface portion 341 is located on the outside of inner peripheral surface 342, with an angle of 90° with respect to optical axis OA.

In addition, the surface having an angle smaller than θ and the surface having an angle greater than θ may either have a constant inclination or a varying inclination (it may be either a straight line or a curved line) in the cross section including optical axis OA. For example, in the case where the angle of the surface having an angle of θ or smaller is constant and is tilted to optical axis OA in the above-described cross-section, the surface having an angle of θ or smaller corresponds to a part of the inner surface of a hollow inverted cone that is rotationally symmetrical about optical axis OA.

### Effects

Light flux controlling member 300 according to the present embodiment includes total reflection surface 320 and refractive emission surface 330, and satisfies light distribution conditions 1 and 2, thus suppressing the degradation in light quality of surface light source device 100. More specifically, OD robustness and dimming performance are improved. In addition, by providing flexibility in the shape design of blind spot region 340, which does not affect the optical path of the light to be controlled, the height of light flux controlling member 300 can be reduced.

### Simulations

### Light Distribution Simulation 1

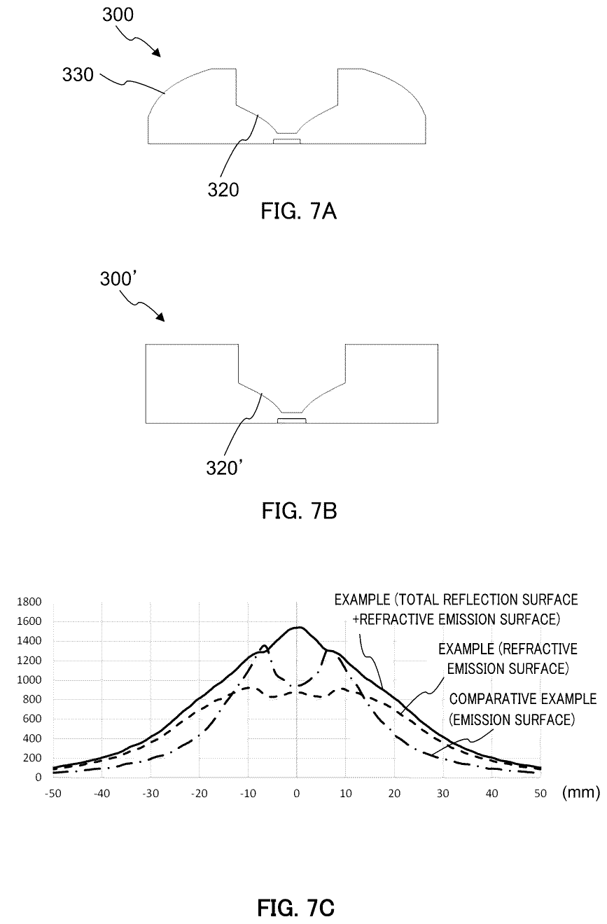

FIG. 7A is a sectional view of light flux controlling member 300 of an example used for a light distribution simulation 1, and FIG. 7B is a sectional view of light flux controlling member 300′ of a comparative example.

As can be seen in FIGS. 7A and 7B, light flux controlling member 300 of the example includes total reflection surface 320 and refractive emission surface 330 that satisfy light distribution conditions 1 and 2, whereas light flux controlling member 300′ of the comparative example includes only total reflection surface 320′ and does not include the refractive emission surface that satisfies light distribution conditions 1 and 2.

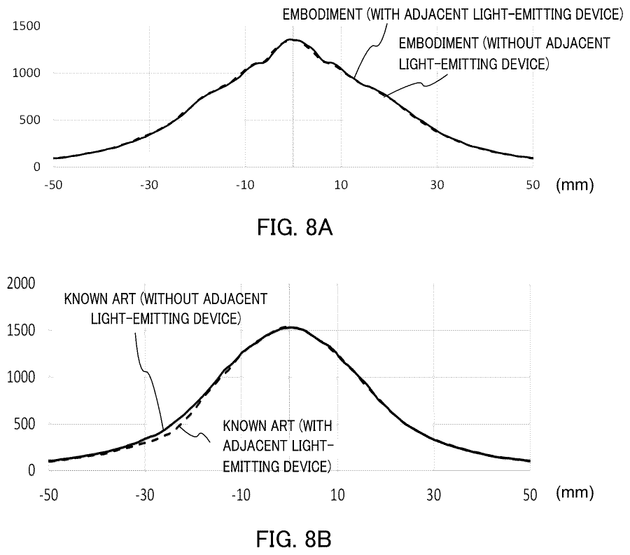

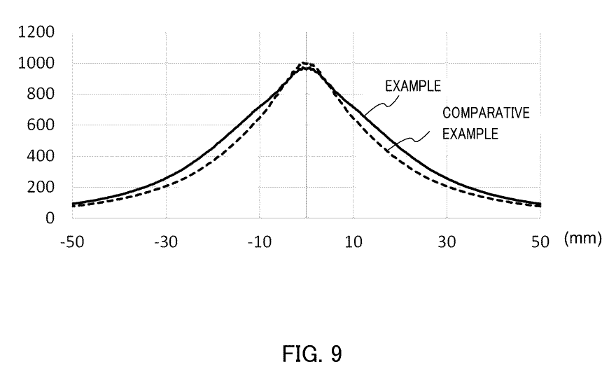

FIG. 7C is a graph illustrating luminance distributions at the light diffusion plate of the surface light source device in light flux controlling member 300 of the example and light flux controlling member 300′ of the comparative example. In FIG. 7C, the abscissa indicates the distance from optical axis OA, and the ordinate indicates the luminance. Note that, the same applies to the graphs illustrated in FIGS. 8A, 8B and 9. In addition, in FIG. 7C, only one light-emitting device is turned on in the surface light source device.

FIG. 7C illustrates variations in luminance distribution depending on the presence/absence of refractive emission surface 330. More specifically, FIG. 7C illustrates luminance distribution of light having reached total reflection surface 320 and refractive emission surface 330 of light flux controlling member 300 (example (total reflection surface+refractive emission surface)), luminance distribution of light emitted from the light-emitting element and directly reached refractive emission surface 330 not through total reflection surface 320 in light flux controlling member 300 (example (refractive emission surface)), and luminance distribution of light emitted from the light-emitting element and emitted not through total reflection surface 320′ (comparative example (emission surface)).

As can be seen in FIG. 7C, comparing the example (refractive emission surface) and the comparative example (emission surface), the graph illustrating the luminance distribution has a more gradual upward convex curve in the example (refractive emission surface). More specifically, in the example (refractive emission surface), the light peaks around ±8 mm are reduced. In view of this, it was found that in the example using the refractive emission surface, the degradation in light quality in the surface light source device is suppressed.

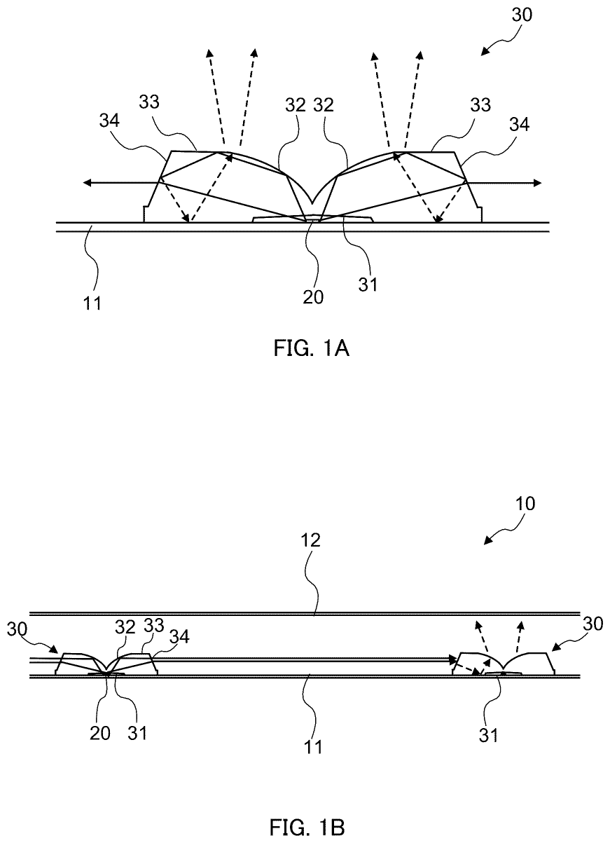

This is considered to be because light flux controlling member 300 of the example includes refractive emission surface 330 and the light distribution of the light that is reflected in the light flux controlling member to reach the light diffusion plate in the region in the vicinity immediately above the light flux controlling member as indicated with the broken line in FIG. 1A is suppressed, thus suppressing degradation in light quality by satisfying light distribution condition 1.

Here, in general, the luminance distribution indicated by a graph of a gradual upward convex curve as that of the example as illustrated in FIG. 7C can suppress degradation in light quality. Specifically, for example, light diffusion plate 120 may be deflected by its own weight, thereby reducing distance OD between light diffusion plate 120 and substrate 210 where light flux controlling member 300 is disposed (see FIG. 3B). In this case, if the luminance distribution is a distribution that is indicated by a graph of a sharp upward convex curve, an excessively bright portion is generated in the surface light source device when distance OD is reduced. On the other hand, with the luminance distribution that is indicated by a graph of a gradual upward convex curve, generation of an excessively bright portion in the surface light source device is suppressed even when distance OD is reduced. That is, OD robustness is improved, thus improving the light quality.

### Light Distribution Simulation 2

In light distribution in Simulation 2, whether the light distribution indicated with the broken line in FIG. 1B is suppressed in light flux controlling member according to the embodiment was examined.

More specifically, in the surface light source device according to the embodiment as illustrated in the upper diagram of FIG. 4, a comparison was made between the luminance distribution of the case where one light-emitting device was turned on with an adjacent light-emitting device unlit, and the luminance distribution of the case where the unlit light-emitting device is omitted in the upper diagram of FIG. 4 such that there is no adjacent light-emitting device. In addition, in a known surface light source device as illustrated in the lower diagram of FIG. 4, a comparison was made between the luminance distribution of the case where one light-emitting device was turned on with an adjacent light-emitting device unlit, and the luminance distribution of the case where one light-emitting device 1 is omitted in the lower diagram of FIG. 4 such that there is no adjacent light-emitting device.

FIG. 8A illustrates a comparison result between the luminance distributions in the surface light source device according to the embodiment, and FIG. 8B illustrates a comparison result between the luminance distributions in a known surface light source device. As can be seen in FIG. 8A, in the surface light source device of the embodiment, the luminance distributions were substantially the same regardless of whether there is an adjacent light-emitting device or not. Conversely, as can be seen in FIG. 8B, in the known surface light source device, the graph has a sharper upward convex curve when there is an adjacent light-emitting device. This is considered to be because in the surface light source device of the embodiment, the light distribution indicated with the broken line in FIG. 1B was suppressed, whereas in the known surface light source device, such suppression was not achieved. From these findings, it can be understood that the surface light source device according to the embodiment has improved local dimming performance.

### Light Distribution Simulation 3

FIG. 9 is a graph illustrating a difference between the luminance distribution obtained with the light flux controlling member of the example having a diameter 4.8 mm and the luminance distribution obtained with the light flux controlling member of the comparative example having a diameter of 5.76 mm. As can be seen in FIG. 9, although the diameter of the light flux control member of the example is smaller than that of the comparative example, the luminance distribution formed a more gradual upward convex curve, indicating that the light spreads over a wider area and the light quality is higher. Specifically, in the embodiment, the full width at half maximum was 6 to 8 mm wider compared to the comparative example.

### Industrial Applicability

The surface light source device of the present invention is applicable to a backlight of liquid crystal display apparatuses, generally-used illumination apparatuses, and the like, for example.

### REFERENCE SIGNS LIST

10, 100 Surface light source device
11, 210 Substrate
12, 120 Light diffusion plate
20, 220 Light-emitting element
30, 300, 300′ Light flux controlling member
31, 310 Incidence surface
32, 320, 320′ Total reflection surface
33 Flat surface reflection surface
34 Emission surface
100′ Display device
102 Display member
110 Housing
112 Bottom plate
114 Top plate
200 Light-emitting device
310a Recess
320a Total reflection surface inner edge
320b Total reflection surface outer edge
330 Refractive emission surface
330a Refractive emission surface inner edge
330b Refractive emission surface outer edge
331 Curved surface portion
332 Outer periphery portion
340 Blind spot region
341 Top surface portion
342 Inner peripheral surface

1. A surface light source device comprising:
a substrate;
a plurality of light-emitting elements disposed on the substrate, each light-emitting element including a light reflection film at a top surface;
a plurality of light flux controlling members respectively disposed to cover the plurality of light-emitting elements; and
a light diffusion plate disposed above the plurality of light flux controlling members,
wherein the light flux controlling member includes:
an incidence surface disposed on a rear side, and configured to allow incidence of light emitted from the light-emitting element,
a total reflection surface disposed on a front side, and configured to totally reflect, toward the substrate side, a part of light entering from the incidence surface, and
a refractive emission surface disposed on the front side and outside of the total reflection surface, and configured to emit light reflected by the total reflection surface and the other part of light entering from the incidence surface, while refracting the light, and
wherein 50% or more of light that is reflected by the total reflection surface and emitted from the refractive emission surface reaches a surface on the substrate side within a distance of L/2 from an intersection C1, where L is a distance between optical axes OA of the plurality of light-emitting elements adjacent to each other, and the intersection C1 is an intersection of the optical axes OA of the light-emitting elements and the substrate.

2. The surface light source device according to claim 1, wherein light that enters through the incidence surface and is emitted from the refractive emission surface not through the total reflection surface includes light that reaches the light diffusion plate within a distance of L/2 from an intersection C2 and light that reaches the light diffusion plate at a distance exceeding L from the intersection C2, where the intersection C2 is an intersection of the optical axes OA of the light-emitting elements and the light diffusion plate.

3. The surface light source device according to claim 1, wherein in a see-through plan view of the light flux controlling member, an inner edge of the total reflection surface is located on inside of an outer edge of the light-emitting element.

4. The surface light source device according to claim 1,
wherein the light flux controlling member includes a blind spot region disposed between the total reflection surface and the refractive emission surface, and
wherein light from the light-emitting element does not reach the blind spot region.

5. A display device comprising the surface light source device according to claim 1.
